(19) United States
(12) Patent Application Publication
(10) Pub. No.: US 2017/0279040 A1
(43) Pub. Date: Sep. 28, 2017

(54) MAGNETIC ELEMENT AND METHOD OF FABRICATION THEREOF

(71) Applicant: AGENCY FOR SCIENCE, TECHNOLOGY AND RESEARCH, Singapore (SG)

(72) Inventors: Michael TRAN, Singapore (SG); Cheow Hin SIM, Singapore (SG)

(21) Appl. No.: 15/514,473

(22) PCT Filed: Sep. 25, 2015
(86) PCT No.: PCT/SG2015/050345

§ 371 Date: Mar. 24, 2017

(30) Foreign Application Priority Data
Sep. 25, 2014 (SG) 10201406062S

(51) Int. Cl. H01L 43/10; H01F 10/12; H01L 43/12; G11C 11/16; H01L 43/08; H01F 10/32; H01F 41/30

(52) U.S. Cl. CPC H01L 43/10; H01F 10/3272; H01F 10/3286; H01F 10/329; H01F 10/3254; H01F 10/123; H01F 41/307; G11C 11/161; H01L 43/08; H01L 43/12

(57) ABSTRACT

There is provided a magnetic element including a ferromagnetic reference layer having a fixed or pinned magnetization direction, a ferromagnetic free layer having a switchable magnetization direction based on spin transfer torque, an insulating spacer layer disposed between the ferromagnetic reference layer and the ferromagnetic free layer such that the ferromagnetic reference layer, the insulating spacer layer, and the ferromagnetic free layer form a magnetic tunnel junction, and at least one multilayer disposed on or in the magnetic tunnel junction, the at least one multilayer including Co/Ni/Pt which exhibits perpendicular magnetic anisotropy. There is also provided a corresponding method of fabricating such a magnetic element and a magnetic memory device including an array of such magnetic elements.

### CROSS-REFERENCE TO RELATED APPLICATION

This application claims the benefit of priority of Singapore Patent Application No. 10201406062S, filed 25 Sep. 2014, the content of which being hereby incorporated by reference in its entirety for all purposes.

### TECHNICAL FIELD

The present invention generally relates to a magnetic element and a method of fabrication thereof, and more particularly, to a spin current driven magnetic element with perpendicular magnetic anisotropy (PMA) for a magnetic memory device, such as a Spin Transfer Torque Magnetic Random Access Memory (STT-MRAM) device.

### BACKGROUND

Magnetic Random Access Memory (MRAM) is a strong competitor of existing memory technologies such as Flash, DRAM and SRAM because of their potential in offering reduction of power consumption through non-volatility, high number of read/write cycles and high speed performance.

A basic MRAM cell (magnetic element) includes a magnetic tunnel junction (MTJ) whereby two ferromagnetic layers, namely a free layer (FL) and a reference layer (RL), are separated by a thin non-magnetic insulating layer (spacer layer). The RL has a fixed magnetization due to a high magnetic anisotropy or a strong exchange coupling to another layer. The FL has a magnetization that is free to rotate in space. The resistance of the cell depends on the relative orientation of the magnetization of the FL and the magnetization of the RL due to the Tunneling Magnetoresistance (TMR) effect. In recent years, it has been found that magnetic momentum can be transferred from the RL to the FL and vice versa, depending on the polarity of the electrical current, across a thin oxide layer (the thin non-magnetic insulating layer). This effect is known as the Spin Transfer Torque (STT). An MTJ therefore forms the basic structure of a MRAM cell for a STT-MRAM, in which the data bit is written by STT and read by TMR.

STT-MRAM devices with perpendicular magnetic anisotropy (PMA) are more advantageous than those based on in-plane magnetic anisotropy in that they provide more efficient current switching, higher thermal stability factor and basically no limitation on the cell aspect ratio. Therefore, improving the STT switching in perpendicularly magnetized MTJ magnetic elements is extremely important for high performance MRAM applications.

An advanced STT-MRAM magnetic element may include additional layers such as a compensating layer and/or a coupling layer, with the former used to cancel the stray field emanating from the bottom pinning layer and the later used to increase the magnetic anisotropy of the FL/RL in order to improve thermal stability. In STT-MRAM applications, PMA materials such as Co/Pt and Co/Pd with strong effective magnetic anisotropy energy density (K_{eff}) have been used conventionally in the MTJ. However, they may not be the best candidates because they face issues of poor growth quality and high damping constant, which can significantly reduce the TMR and increase the critical switching current density of the MTJ, respectively.

A need therefore exists to provide a spin current driven magnetic element with PMA that seeks to overcome, or at least ameliorate, one or more of the deficiencies of conventional magnetic elements, such as improved thermal stability, high TMR ratio and/or low critical switching density. It is against this background that the present invention has been developed.

### SUMMARY

According to a first aspect of the present invention, there is provided a magnetic element comprising:
a ferromagnetic reference layer having a fixed or pinned magnetization direction;
a ferromagnetic free layer having a switchable magnetization direction based on spin transfer torque;
an insulating spacer layer disposed between the ferromagnetic reference layer and the ferromagnetic free layer such that the ferromagnetic reference layer, the insulating spacer layer, and the ferromagnetic free layer form a magnetic tunnel junction; and
at least one multilayer disposed on or in the magnetic tunnel junction, the at least one multilayer including Co/Ni/Pt which exhibits perpendicular magnetic anisotropy.

In various embodiments, the at least one multilayer is disposed on the magnetic tunnel junction such that the at least one multilayer constitutes a compensating layer configured to cancel an external magnetic field towards the ferromagnetic free layer emanating from outside the magnetic tunnel junction.

In various embodiments, the magnetic element further comprises a pinning layer ferromagnetically coupled to the ferromagnetic reference layer for pinning the magnetization direction of the ferromagnetic reference layer to the pinning layer, wherein the pinning layer comprises one or more multilayers, each multilayer includes Co/Ni/Pt which exhibits perpendicular magnetic anisotropy.

In various embodiments, at least one of the compensating layer and the pinning layer is configured such that the switching field of the compensating layer is less than the switching field of the pinning layer.

In various embodiments, the ferromagnetic reference layer comprises a first ferromagnetic material layer and the at least one multilayer.

In various embodiments, the ferromagnetic reference layer further comprises:
a second ferromagnetic material layer; and
an interlayer disposed between the first ferromagnetic material layer and the second ferromagnetic material layer for exchange coupling between the first ferromagnetic material layer and the second ferromagnetic material layer, wherein the at least one multilayer is disposed between the first ferromagnetic material layer and the interlayer.

In various embodiments, the at least one multilayer is disposed on the first ferromagnetic material layer such that the at least one multilayer constitutes a diffusion barrier for preventing diffusion of one or more elements of the first ferromagnetic layer to the insulating spacer layer.

In various embodiments, the first ferromagnetic material layer comprises at least one of (Co/Pd)ₙ, (CoFe/Pd)ₙ, (Co/Pt)ₙ, and (CoFe/Pt)ₙ, where n is a stacking number and is at least 1.

In various embodiments, the ferromagnetic free layer comprises a first ferromagnetic material layer and the at least one multilayer.

In various embodiments, the ferromagnetic free layer further comprises an interlayer disposed between the first ferromagnetic material layer and the at least one multilayer for exchange coupling between the first ferromagnetic material layer and the at least one multilayer.

In various embodiments, the first ferromagnetic material layer comprises at least one of CoFeB.

In various embodiments, the at least one multilayer is a multilayer stack including (Co/Ni/Pt)ₙ, where n is a stacking number and is at least 1.

In various embodiments, n is a number from 2 to 30.

In various embodiments, the thickness of Pt in the at least one multilayer is greater than 0 Angstrom to about 10 Angstrom.

According to a second aspect of the present invention, there is provided a method of fabricating a magnetic element, the method comprising:
forming a ferromagnetic reference layer having a fixed or pinned magnetization direction;
forming a ferromagnetic free layer having a switchable magnetization direction based on spin transfer torque;
forming an insulating spacer layer between the ferromagnetic reference layer and the ferromagnetic free layer such that the ferromagnetic reference layer, the insulating spacer layer, and the ferromagnetic free layer form a magnetic tunnel junction; and
forming at least one multilayer on or in the magnetic tunnel junction, the at least one multilayer including Co/Ni/Pt which exhibits perpendicular magnetic anisotropy.

In various embodiments, forming the at least one multilayer comprises forming the at least one multilayer on the magnetic tunnel junction such that the at least one multilayer constitutes a compensating layer configured to cancel an external magnetic field towards the ferromagnetic free layer emanating from outside the magnetic tunnel junction.

In various embodiments, forming the ferromagnetic reference layer comprises forming a first ferromagnetic material layer, and forming the at least one multilayer comprises forming the at least one multilayer as part of the ferromagnetic reference layer.

In various embodiments, forming the ferromagnetic reference layer further comprises:
forming a second ferromagnetic material layer; and
forming an interlayer between the first ferromagnetic material layer and the second ferromagnetic material layer for exchange coupling between the first ferromagnetic material layer and the second ferromagnetic material layer, wherein the at least one multilayer is formed between the first ferromagnetic material layer and the interlayer.

In various embodiments, forming the ferromagnetic free layer comprises forming a first ferromagnetic material layer and forming the at least one multilayer comprises forming the at least one multilayer as part of the ferromagnetic free layer.

According to a third aspect of the present invention, there is provided a magnetic memory device comprising an array of magnetic elements according to the above-mentioned first aspect of the present invention.

### BRIEF DESCRIPTION OF THE DRAWINGS

Embodiments of the present invention will be better understood and readily apparent to one of ordinary skill in the art from the following written description, by way of example only, and in conjunction with the drawings, in which:

FIG. 1 depicts a schematic drawing of a magnetic element according to an embodiment of the present invention;

FIGS. 2A to 2C depict three plots showing various magnetic properties of the multilayer(s) according to an example embodiment of the present invention, measured as a function of the thickness of Pt in the multilayer(s) in an example experiment;

FIG. 3 depicts a schematic drawing of a magnetic element according to a first example embodiment of the present invention;

FIG. 4A depicts a schematic drawing of a magnetic element according to a second example embodiment of the present invention in the case where the magnetic element is a bottom pinned magnetic element;

FIG. 4B depicts a schematic drawing of the reference layer of the magnetic element according to the second example embodiment;

FIG. 4C depicts a schematic drawing of a conventional reference layer of a magnetic element for comparison with the reference layer according to the second example embodiment;

FIG. 5A depicts a schematic drawing of a magnetic element according to a third example embodiment of the present invention;

FIG. 5B depicts a schematic drawing of the reference layer of the magnetic element according to the third example embodiment;

FIG. 5C depicts a schematic drawing of a conventional reference layer of a magnetic element for comparison with the reference layer according to the third example embodiment;

FIG. 6 depicts a schematic drawing of a magnetic element according to a fourth example embodiment of the present invention in the case where the magnetic element is a bottom pinned magnetic element;

FIG. 7 depicts a schematic drawing of a magnetic element according to a fifth example embodiment of the present invention in the case where the magnetic element is a top pinned magnetic element;

FIG. 8 depicts a flow diagram of a method of fabricating a magnetic element according to an embodiment of the present invention; and

FIG. 9 depicts a schematic drawing of a magnetic memory device according to an example embodiment.

### DETAILED DESCRIPTION

Embodiments of the present invention provide a magnetic element for a magnetic memory device (such as a STT-MRAM device) that seeks to overcome, or at least ameliorate, one or more of the deficiencies of conventional magnetic elements.

As described in the background, perpendicular magnetic anisotropy (PMA) material layer(s) has been conventionally incorporated in magnetic elements in an attempt to improve the performance of certain aspect(s) of the magnetic element. For example, PMA materials such as Co/Pt and Co/Pd have typically been used conventionally in the magnetic tunnel junction (MTJ) for their strong effective magnetic anisotropy energy density (K_{eff}). However, simply incorporating such a PMA material with strong K_{eff} to improve the PMA of the MTJ may in turn cause other issues, such as poor growth quality and high damping constant (e.g., if used in contact with the free layer), which can significantly reduce the Tunneling Magnetoresistance (TMR) and increase the critical switching current density of the MTJ, respectively.

Embodiments of the present invention provide one or more multilayers (or multilayer stack) with PMA that can be incorporated into a spin current driven magnetic element to seek to address one or more of the above-mentioned deficiencies of conventional magnetic elements. In particular, the multilayer includes Cobalt/Nickel/Platinum (Co/Ni/Pt) exhibiting PMA. The multilayer stack can be defined as (Co/Ni/Pt)ₙ, where n is the stacking number and is at least 1. As will be described later according to various embodiments of the present invention, the one or more multilayers are incorporated in the magnetic element for improving the performance(s) of the magnetic element while minimizing or preventing the introduction of undesirable side effects such as a reduction in TMR or an increase in the critical switching current density of the MTJ.

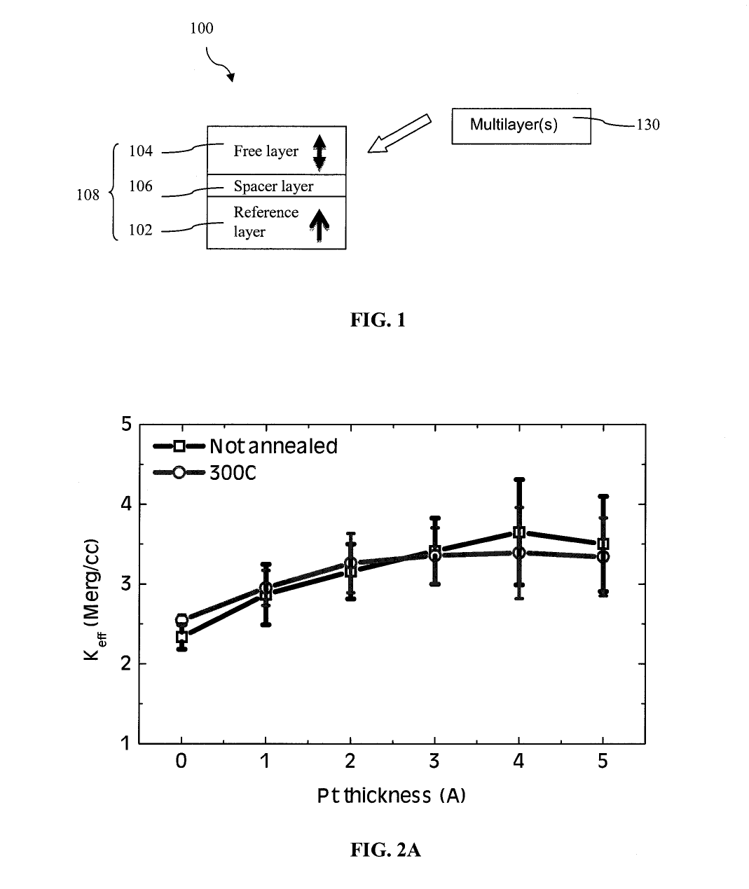

FIG. 1 depicts a schematic drawing of a magnetic element 100 according to an embodiment of the present invention. The magnetic element 100 comprises a ferromagnetic reference layer 102 having a fixed or pinned magnetization direction, a ferromagnetic free layer 104 having a switchable magnetization direction based on spin transfer torque, and an insulating spacer layer 106 disposed between the ferromagnetic reference layer 102 and the ferromagnetic free layer 104 such that the ferromagnetic reference layer 102, the insulating spacer layer 106, and the ferromagnetic free layer 104 form a magnetic tunnel junction 108. In particular, the magnetic element 100 further comprises at least one multilayer 130 disposed on or in the magnetic tunnel junction 108, whereby the at least one multilayer 130 includes Co/Ni/Pt which exhibits PMA.

The multilayer(s) 130 has a net effective PMA energy and was surprisingly found by the present inventors to possess various advantageous magnetic properties over conventional PMA material layers. For example, the multilayer(s) 130 has a lower damping factor compared to conventional PMA materials such as Co/Pt multilayer or Co/Pd multilayer. Furthermore, it was surprisingly found by the present inventors that the effective magnetic anisotropy energy density (K_{eff}) of the multilayer(s) 130 can advantageously be tuned by varying the thickness of Pt, for example and without limitation, from greater than 0 to about 10 Angstrom (Å) according to various embodiments of the present invention, while remaining relatively stable against annealing up to 300° C. As an exemplary illustration, Table 1 below summarizes the magnetic properties of various conventional PMA materials used in typical MTJs and the magnetic property of the present multilayer(s) 130 according to an example embodiment of the present invention, as measured by Alternating Gradient Magnetometry.

TABLE 1

| | [Co/Pt] | [Co/Pt] | | |
|---|---|---|---|---|
| | multilayers | superlattices | [Co/Ni] | [Co/Ni/Pt] |
| Best K_{eff} | ~8 | ~7 | ~2.25 | ~2.25 to 3.5 |
| (Merg/cm³) | | | | |
| Mₛ (emu/cm³) | 1000 | 700 | 700 | 700 |

As can be seen from Table 1, the present multilayer(s) 130 advantageously enables a tunable value of K_{eff} at a constant saturation magnetization Mₛ. It can also be observed that the K_{eff} of the present multilayer(s) 130 is in the intermediate range between that of conventional multilayer Co/Ni and conventional Co/Pt-based multilayers and superlattices. This shows that the multilayer(s) 130 is able to have a value of K_{eff} between that of Co/Ni and that of Co/Pt.

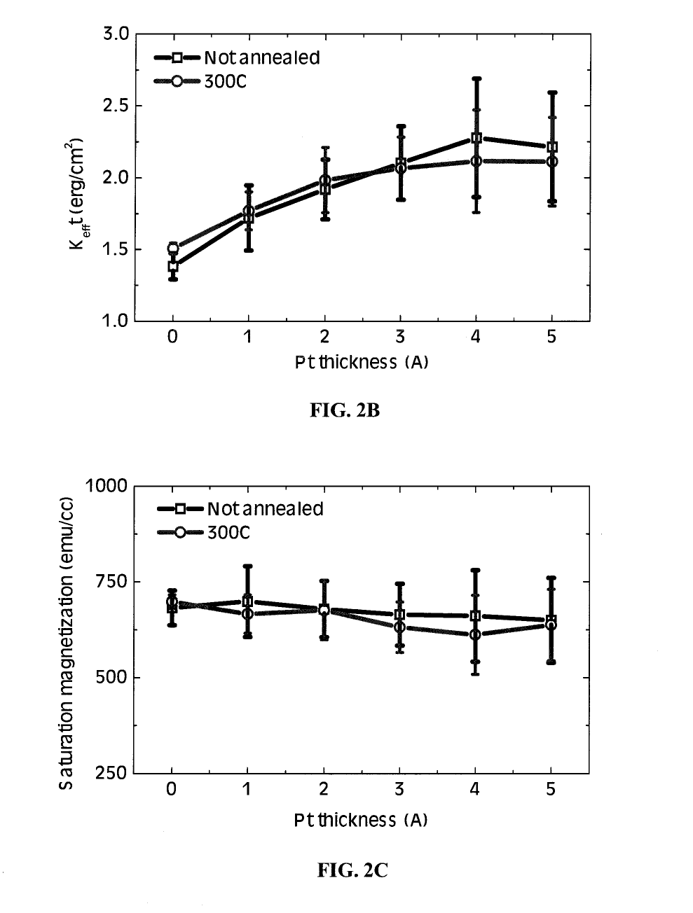

For illustration purposes only, FIGS. 2A to 2C depict three plots showing various magnetic properties of the multilayer(s) 130 (with margin of error shown) according to an example embodiment of the present invention, measured as a function of the thickness of Pt in the multilayer(s) 130 in an example experiment. In the example experiment, the multilayer(s) 130 has 8 stacks of Co/Ni/Pt and the thicknesses of Co and Ni in each multilayer 130 are 0.3 Å and 0.6 Å, respectively. It can be appreciated that the above stacking number and the above thicknesses of Co and Ni are merely exemplary and the present invention is not limited as such. FIG. 2A depicts a plot of the K_{eff} (Merg/cc) as a function of the thickness of Pt (Å) in the multilayer(s) 130, FIG. 2B depicts a plot of the surface anisotropy (K_{eff}×t (Merg/cm²)) as a function of the thickness of Pt (Å) in the multilayer(s) 130, and FIG. 2C depicts a plot of the saturation magnetization (Mₛ) as a function of the thickness of Pt (Å) in the multilayer(s) 130. From FIG. 2A, it can be observed that the K_{eff} of the multilayers 130 can be varied/tuned by varying the thickness of the Pt and increases up to 3.5 Merg/cc when the thickness of the Pt is above 2 Å. From FIG. 2B, it can be seen that the surface anisotropy (K_{eff}×t) of the multilayers 130, which is an indication of thermal stability, reaches 2.1 erg/cm² when the thickness of Pt is 4 Å. From FIG. 2C, it is demonstrated that the saturation magnetization (Mₛ) of the multilayers 130 advantageously remains relatively constant, independent of the thickness of the Pt. Each of the plots shown in FIGS. 2A, 2B and 2C shows the experimental results for the case where the multilayer(s) 130 have not been annealed and the case where the multilayer(s) 130 has been annealed at 300° C. for about 1 hour in vacuum. By comparing both cases, it can be observed that the magnetic properties of the multilayer stack 120 are stable after being annealed at 300° C. for about 1 hour in vacuum. Accordingly, from the above experimental results, it is shown that the K_{eff} and the K_{eff}×t can advantageously be varied/tuned by varying the thickness of the Pt layer in the exemplary range of 0 to 5 Å. It can also be concluded from the results that the Co/Ni/Pt multilayers 130 are advantageously compatible with typical MTJs processes which require annealing up to 300° C. for 1 hour in vacuum.

In the magnetic element 100, the magnetization of the free layer 104 can be switched/reversed using spin transfer torque so that the magnetization of the reference layer 102 and the free layer 104 can be substantially aligned in either a parallel or an antiparallel manner. The resistance of the magnetic element 100 will be low when the orientation of their magnetization is aligned parallel and will be high when the orientation of their magnetization is aligned antiparallel. This variation in the resistance of the magnetic element 100 can thus be used to indicate the state of the magnetic element 100 and can therefore store data. For example, data “0” may correspond to a low resistance state while data “1” may correspond to a high resistance state. When a write current passes through the magnetic element 100, the magnetization of the free layer 104 can be switched or maintained, depending on the direction of the spin angular momentum of the electrons incident on the free layer 104.

Throughout the present specification, it can be understood that when a layer or element is referred to as being “on” another layer or element, the layer or element can be directly on another layer or element (i.e., without any intermediate/intervening layers or elements therebetween) or indirectly on another layer or element (i.e., with one or more intermediate layers or elements therebetween). Therefore, unless stated otherwise, such an expression should be interpreted to cover both cases.

According to various embodiments, the multilayer(s) 130 can be incorporated in the magnetic element 100 in various ways to improve the performance(s) of the magnetic element 100. Hereinafter, various exemplary ways of incorporating the multilayer(s) 130 in the magnetic element 100 and the associated improve in performance(s) will be described according to example embodiments of the present invention. However, it will be understood that the multilayer(s) 130 may be incorporated in the magnetic element 100 in various other ways as suitable/appropriate and the present invention is not limited to the example embodiments described hereinafter. Furthermore, the present invention may be embodied in many different forms and should not be construed as limited to the example embodiments described hereinafter. Rather, these example embodiments are provided so that this disclosure will be thorough and complete, and will fully convey the scope of the present invention to those skilled in the art.

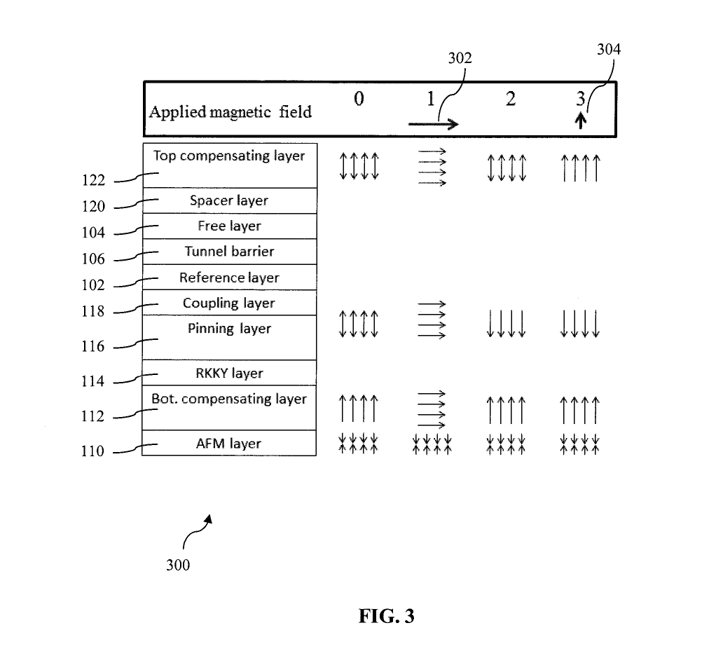

FIG. 3 depicts a schematic drawing of a magnetic element 300 according to a first example embodiment of the present invention. The magnetic element 300 comprises a stack of layers formed on a substrate (not shown). As shown in FIG. 3, the magnetic element 300 comprises an anti-ferromagnetic (AFM) layer 110, a bottom compensating layer 112 coupled anti-ferromagnetically to a pinning layer 116 via a RKKY layer 114 to form a synthetic antiferromagnetic (SAF) structure. The magnetic element 300 further comprises a coupling layer 118 to ferromagnetically couple the pinning layer 116 to a ferromagnetic reference layer 102, a tunnel barrier 106, a ferromagnetic free layer 104, a spacer layer 120 and a top compensating layer (or field cancellation layer) 122. The reference layer 102, the tunnel barrier 106, and the free layer 104 form the MTJ. The AFM layer 110 acts as a pinning layer for the SAF and also as a spin depolarization layer for reference layer stabilization. For example, the AFM layer 110 may include, but not limited to, IrMn and/or PtMn, which are antiferromagnetic materials and for example are used to increase the pinning strength of the ferromagnetic layer (the bottom compensating layer 112) which is in direct contact thereto. The free layer 104 is capable of switching its magnetic direction/orientation relative to the reference/fixed layer 102, and may be made of any useful ferromagnetic alloys such as, but not limited to, CoFeB. The main function of the top compensating layer 122, which has an opposite magnetization direction to the pinning layer 116, is to cancel the external magnetic field towards the free layer 104 emanating from outside the MTJ (e.g., emanating from the pinning layer 116) as much as possible, thereby minimizing the offset field in the free layer 104.

The first example embodiment illustrates an example application of providing the at least one multilayer 130 with a configurable/tunable range of perpendicular magnetic anisotropy as described hereinbefore at relatively constant saturation magnetization, and relatively lower damping constant for an advanced MRAM structure. In particular, in the first example embodiment, the at least one multilayer 130 is disposed on the MTJ such that the at least one multilayer 130 constitutes a compensating layer (the top compensating layer or field cancellation layer) 122 configured to cancel an external magnetic field towards the ferromagnetic free layer 104 emanating from outside the MTJ. In order for the top compensating layer 122 to be able to cancel the external magnetic field, the magnetization of the top compensating layer 122 and/or the magnetization of the pinning layer have to be configured to be in opposite but with equal magnetic moment. In this regard, this is possible if the switching field of the top compensating layer 122 is smaller than the pinning layer 116 such that an applied magnetic field may be applied to only switch the magnetization of the top compensating layer 122 (i.e., without also causing the magnetization of the pinning layer 116 to switch) as shown in FIG. 3. This can be considered as a 2-step magnetization initialization with applied magnetic field. As an exemplary illustration with reference to FIG. 3, a first magnetic field 302 may be applied in the plane of the MTJ, so that the magnetizations of the top compensating layer 122, the pinning layer 116, and the bottom compensating layer 112 become in plane. The magnetic field is then reduced to zero, and the bottom compensating layer 112 aligns itself with a deterministic direction depending on the AFM layer 110. As a result, the pinning layer 116 aligns antiferromagnetically to the bottom compensating layer 112. The top compensating layer 122 has a magnetization direction which is not deterministic, but can be aligned with a second magnetic field 304 applied, perpendicular to the MTJ, without destroying/overwriting the magnetization initialization of the SAF (layers 112 and 116).

In order to only switch the magnetization of the top compensating layer 122, it is thus necessary to ensure that the switching field of the top compensating layer 122 is smaller than the pinning layer 116. In this regard, as described hereinbefore, the effective magnetic anisotropy energy density (K_{eff}) of the multilayer(s) 130 forming the top compensating layer 122 can advantageously be tuned by varying the thickness of Pt. Therefore, the multilayer(s) 130 makes it possible to obtain a top compensating layer 122 to achieve the above-mentioned technical effect of cancelling an external magnetic field towards the ferromagnetic free layer 104 emanating from outside the MTJ.

In various embodiments, the top compensating layer 122 comprises (Co(t1)/Ni(t2)/Pt(t3))ₙ, where n is the stacking number ranging from 2 to 30. In an embodiment, it has been found by the present inventors that the larger the value of n, the larger the overall stray field, therefore n can be used/selected to tune the strength of the stray field for compensating the above-mentioned external magnetic field. The thickness (t2) of Ni is preferably greater than the thickness (t1) of Co, and the thickness (t3) of Pt is preferably greater than 0 to about 10 Å. In an embodiment, the pinning layer 116 may also comprise one or more multilayers including Co/Ni/Pt, such as (Co(t1)/Ni(t2)/Pt(t3))ₙ, where n is the stacking number ranging from 2 to 30. The number n of stacks/repeats in the top compensating layer 122 need not be the same as that of the pinning layer 116 and the thicknesses t1, t2 and t3 can be configured/varied to fine-tuning the switching field of each layer. For example, as shown in FIGS. 2A to 2C, the saturation magnetization of the multilayer stack 130 remains relatively constant while K_{eff} (and thus switching field) can be varied by changing the thickness (t3) of the Pt layer, which is an important criteria for the above-mentioned technical effect to be realized.

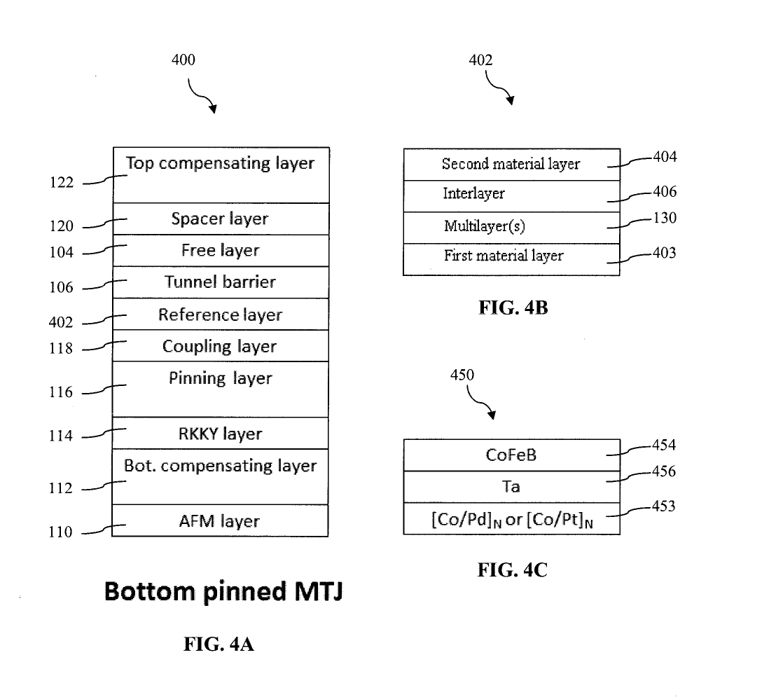

FIG. 4A depicts a schematic drawing of a magnetic element 400 according to a second example embodiment of the present invention in the case where the magnetic element 400 is a bottom pinned magnetic element. The magnetic element 400 is the same as the magnetic element 300 as illustrated in FIG. 3, except that at least one multilayer 130 is incorporated in the reference layer 102 to improve the performance(s) of the magnetic element 400. In the second example embodiment, it will be understood that the top compensating layer (field cancellation layer) 122 may also include at least one multilayer 130 as described with reference with FIG. 3 or may be any conventional compensating layer known in the art configured for cancelling the external magnetic field towards the free layer 104. Therefore, the description of the layers/elements of the magnetic element 400 which are the same or similar as the corresponding layers/elements of the magnetic element 300 described hereinbefore may not be repeated for clarity and conciseness. It can be understood that the same or corresponding layers/elements may be denoted using the same reference numerals throughout the drawings.

FIG. 4B depicts a schematic drawing of the reference layer 102 of the magnetic element 400 according to the second example embodiment. The reference layer 102 comprises a first ferromagnetic material layer 403 and the at least one multilayer 130. As shown in FIG. 4B, the multilayer(s) 130 is disposed on the first ferromagnetic material layer 402, and in various embodiments, is disposed directly thereon. The reference layer 102 further comprises a second ferromagnetic material layer 404, and an interlayer 406 disposed between the first ferromagnetic material layer 402 and the second ferromagnetic material layer 404 for exchange coupling between the first ferromagnetic material layer 402 and the second ferromagnetic material layer 404. As can be seen from FIG. 4B, at least one multilayer 130 is disposed between the first ferromagnetic material layer 403 and the interlayer 406.

As an example, the reference layer 402 may be provided in the form of a multi-layered structure whereby a multilayer(s) 130 of (Co/Ni/Pt)ₙ, is formed on top of a strongly perpendicularly magnetized multilayer (first ferromagnetic material layer) 403 including at least one of (Co/Pt)ₙ, (CoFe/Pd)ₙ, (Co/Pt)ₙ, (CoFe/Pt)ₙ, where the subscript n denotes the stacking number and is at least 1. The interlayer 406 may for example be made of Ta to provide exchange coupling between the multilayer(s) of (Co/Ni/Pt)ₙ 130 and CoFeB (second ferromagnetic material layer) 404 lying adjacent to the MgO tunnel barrier 106.

For illustration and comparison purposes only in the second example embodiment, FIG. 4C depicts a schematic drawing of a conventional reference layer 450 of a magnetic element. The conventional reference layer 450 includes a strongly perpendicularly magnetized multilayer 453 of (Co/Pd)ₙ or (Co/Pt)ₙ which is exchange-coupled to CoFeB 450 via a Ta interlayer 456. However, with such a conventional configuration of the reference layer as shown in FIG. 4C, for example, Pd diffusion towards MgO during annealing (in the case of (Co/Pd)ₙ) and poor growth quality of (Co/Pt)ₙ leading to high roughness (in the case of ((Co/Pt)ₙ) both undesirably lead to a reduction in the TMR. In contrast, according to the second embodiment of the present invention, the multilayer(s) of (Co/Ni/Pt)ₙ 130 between the interlayer 406 and the first ferromagnetic material layer 403 may function as a diffusion barrier as well as providing a smoother surface morphology for the growth of subsequent layers (which provides a smooth transition between the first ferromagnetic material layer 403 (e.g., Co/Pd and Co/Pt) and the second ferromagnetic material layer 404 (e.g., CoFeB). That is, the multilayer(s) 130 is disposed on the first ferromagnetic material layer 403 such that the one multilayer(s) 130 may function as a diffusion barrier for preventing diffusion of one or more elements of the first ferromagnetic layer 403 to the insulating spacer layer 106. Therefore, incorporating the multilayer(s) 130 into the reference layer 402 in the manner as described in the second example embodiment can result in the magnetic element 400 having better performance in TMR than conventional magnetic elements such as those having a reference layer configuration similar to that shown in FIG. 4C.

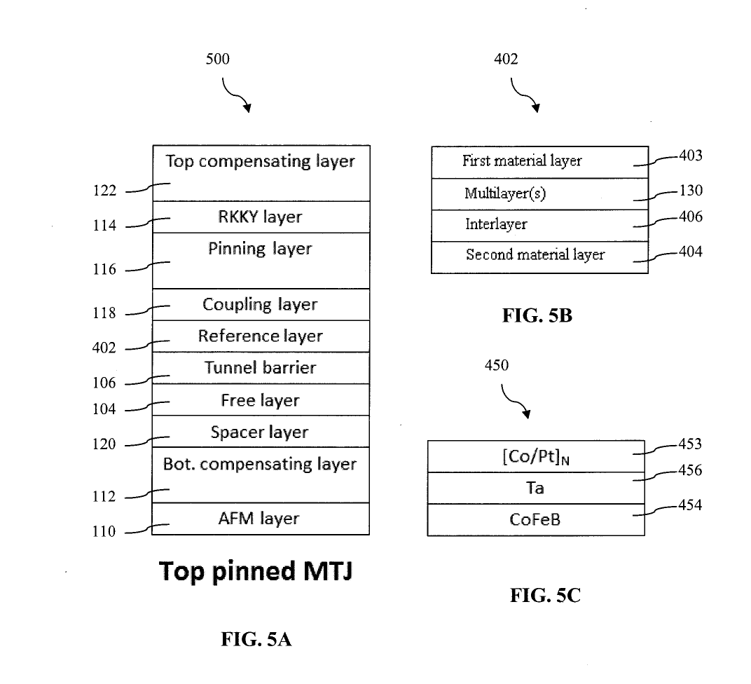

FIG. 5A depicts a schematic drawing of a magnetic element 500 according to a third example embodiment of the present invention. The magnetic element 500 is the same as the magnetic element 400 as illustrated in FIG. 4, except that the magnetic element 500 is configured as a top pinned magnetic element. Therefore, the layer sequence of the magnetic element 500 is simply a reverse of the layer sequence of the magnetic element 400. Thus, the description of the layers/elements of the magnetic element 500 which are the same or similar as the corresponding layers/elements of the magnetic element 400 described hereinbefore are not be repeated for clarity and conciseness. FIG. 5B depicts a schematic drawing of the reference layer of the magnetic element according to the third example embodiment. For illustration and comparison purposes only in the third example embodiment, FIG. 5C depicts a schematic drawing of a conventional reference layer 450 of a magnetic element.

In the magnetic element 500 according to the third example embodiment, for example, the multilayer(s) layer 130 may act as a seed layer for the first ferromagnetic material layer 403 (e.g., (Co/Pt)ₙ)) to mitigate the problem of difficulty in growing the first ferromagnetic material layer 403 by sputtering in forming the reference layer 402 in a top pinned MTJ structure 500.

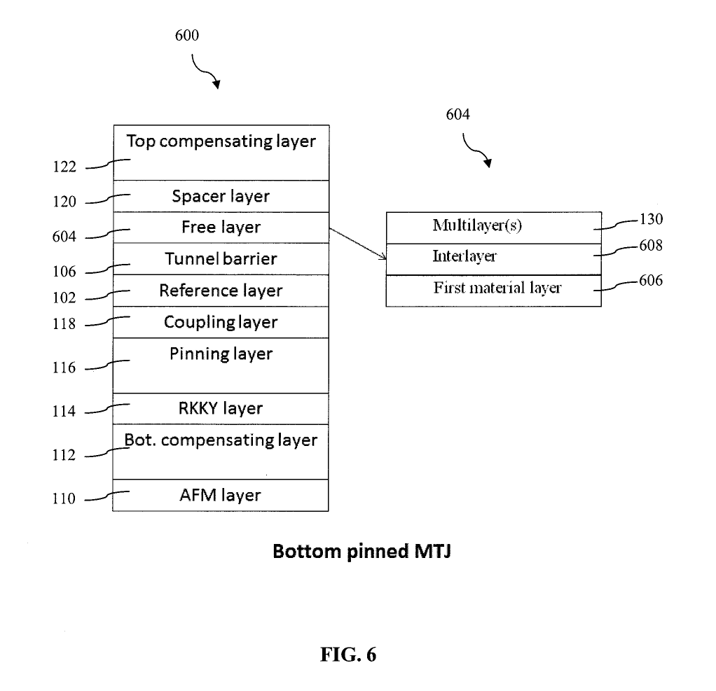

FIG. 6 depicts a schematic drawing of a magnetic element 600 according to a fourth example embodiment of the present invention in the case where the magnetic element 600 is a bottom pinned magnetic element. The magnetic element 600 is the same as the magnetic element 300 as illustrated in FIG. 3, except that at least one multilayer 130 is incorporated in the free layer 104 to improve the performance(s) of the magnetic element 600. In the fourth example embodiment, it will be understood that the top compensating layer (field cancellation layer) 122 may also include at least one multilayer 130 as described with reference with FIG. 3 or may be any conventional compensating layer known in the art configured for cancelling the external magnetic field towards the free layer 104. It will also be understood that the reference layer 102 may also include at least one multilayer 130 as described with reference to FIGS. 4A and 4B or may be any conventional reference layer. Therefore, the description of the layers/elements of the magnetic element 600 which are the same or similar as the corresponding layers/elements of the magnetic element 300/400 described hereinbefore may not be repeated for clarity and conciseness.

FIG. 6 also depicts a schematic drawing of the free layer 604 of the magnetic element 600 according to the fourth example embodiment. The free layer 604 comprises a first ferromagnetic material layer 606, the at least one multilayer 130, and an interlayer 608 disposed between the first ferromagnetic material layer 606 and the at least one multilayer 130 for exchange coupling between the first ferromagnetic material layer 606 and the at least one multilayer 130.

In the fourth example embodiment, the free layer 604 may be provided in the form of a multi-layered structure 130 with a multilayer(s) of (Co/Ni/Pt)ₙ, and CoFeB (first ferromagnetic material layer) 606 sandwiching a Ta interlayer 608 therebetween. Incorporating the multilayer(s) 130 of (Co/Ni/Pt)ₙ, in the manner as described in the fourth example embodiment advantageously improve the thermal stability of the free layer 604 of the magnetic element 600 without undesirably affecting the critical switching current density of the magnetic element 600 due to its smaller damping constant.

In this regard, one of the present challenges in MRAM technology is to be able to maintain a high thermal stability factor (Δ) of the free layer at reduced dimension. By defining Δ=K_{eff}V/K_{b}T, where K_{eff} denotes the effective magnetic anisotropy energy density, V denotes the volume of the free layer, K_{b} denotes the Boltzmann constant, and T denotes the absolute temperature. Conventionally, the free layer may comprise of a single CoFeB layer. However, material characteristic and thickness limitation to attain PMA restricts the value of Δ for CoFeB. For example, in the magnetic element disclosed in Lam et al. (“MgO overlayer thickness dependence of perpendicular magnetic anisotropy in CoFeB thin films”, Journal of the Korean Physical Society, Vol. 62, No. 10, pp. 1461-1464 (2013)), a value of 1.74 erg/cm² was reported for the magnetic anisotropy of the CoFeB free layer. This value is lower than that achieved using the multilayer(s) 130 of (Co/Ni/Pt)ₙ, as for example illustrated in FIG. 2B for Pt thickness greater than 0.2 nm. In particular, according to the fourth example embodiment, the multilayer of (Co/Ni/Pt)ₙ, may be coupled to CoFeB through a Ta interlayer. This configuration advantageously ensures that a high thermal stability can be achieved without degrading the TMR ratio. As another comparative example, the magnetic element disclosed in Ishikawa et al. (“Magnetic properties of MgO—[Co/Pt] multilayers with a CoFeB insertion layer”, Journal of Applied Physics 11, 17C721 (2013)), Co/Pt was employed to couple to CoFeB through a Ta interlayer for improving the MTJ properties. However, with such a conventional configuration, the spin scattering property of Pt and its high damping factor can significantly increase the critical switching current density of the free layer. In contrast, according to the fourth example embodiment, the multilayer(s) 130 of (Co/Ni/Pt)ₙ, is incorporated into the free layer 604 (which thus functions as a coupling layer) to improve the thermal stability of the free layer 604. The multilayer(s) 130 is found by the present inventors to be superior over conventional layers such as (Co/Pd) and (Co/Pt) since, for example, the multilayer 130 has a lower damping constant hence leading to a smaller critical switching current density. Accordingly, the fourth embodiment enables the thermal stability of the magnetic element 600 to be improved yet advantageously maintaining lower critical current density with its smaller damping constant.

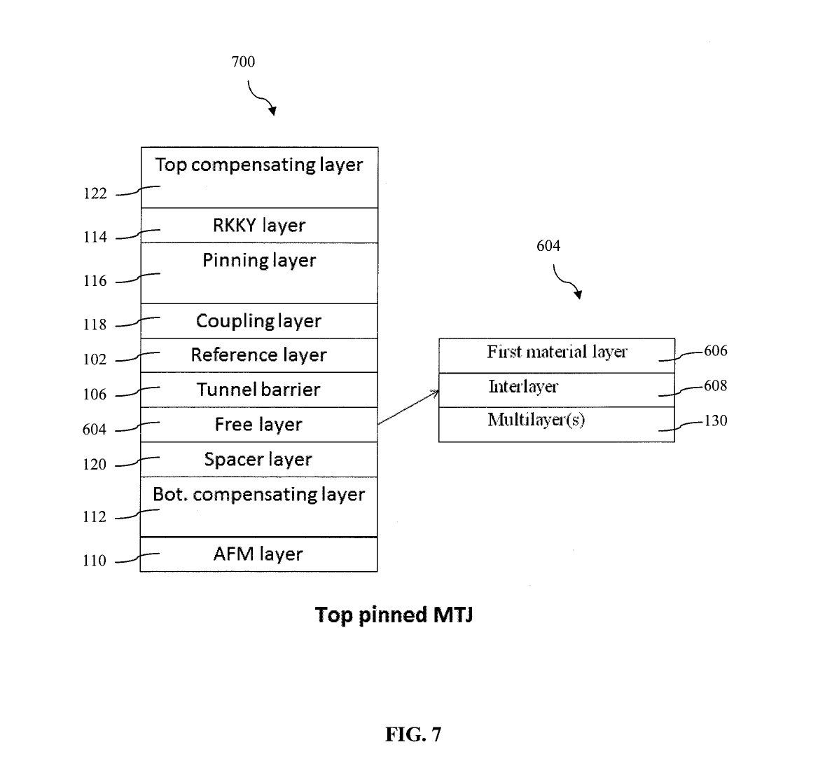

FIG. 7 depicts a schematic drawing of a magnetic element 700 according to a fifth example embodiment of the present invention. The magnetic element 700 is the same as the magnetic element 600 as illustrated in FIG. 6, except that the magnetic element 700 is configured as a top pinned magnetic element. Therefore, the layer sequence of the magnetic element 700 is simply a reverse of the layer sequence of the magnetic element 600. Thus, the description of the layers/elements of the magnetic element 700 which are the same or similar as the corresponding layers/elements of the magnetic element 600 described hereinbefore are not be repeated for clarity and conciseness. The advantages of incorporating the multilayer(s) 130 in the free layer 604 in the top pinned magnetic element 700 are generally the same as or similar to the advantages as described above for the bottom pinned magnetic element 600.

As mentioned hereinbefore, it will be understood by a person skilled in the art that the multilayer 130 can be incorporated in the magnetic element 100 in various ways to improve the performance(s) of the magnetic element 100, and the present invention is not limited to incorporating the multilayer 130 in the magnetic element 100 in the manner as described hereinbefore in the exemplary embodiments. It will also be understood that the magnetic elements as described hereinbefore with reference to FIGS. 3 to 7 are merely examples for illustration purposes only and the magnetic elements according to the present invention are not limited to having such specific structures/configurations disclosed. It will be understood that the magnetic elements according to the present invention can be modified to have any type of configuration/structure as suitable/appropriate, as long as the magnetic elements are spin current driven and has incorporated therein the multilayer(s) 130 of (Co/Ni/Pt). Furthermore, the present disclosure may describe embodiments of the magnetic element which can be operable in various orientations, and it thus should be understood that any of the terms “top”, “bottom”, “base”, “down”, “sideways”, “downwards”, etc., when used in the description herein are used for convenience and to aid understanding of relative positions or directions, and not intended to limit the orientation of the magnetic element 200. It will also be understood by a person skilled in the art that schematic drawings of the magnetic elements shown in the Figures may not be drawn to scale, and that various lengths, sizes and regions may be exaggerated for clarity.

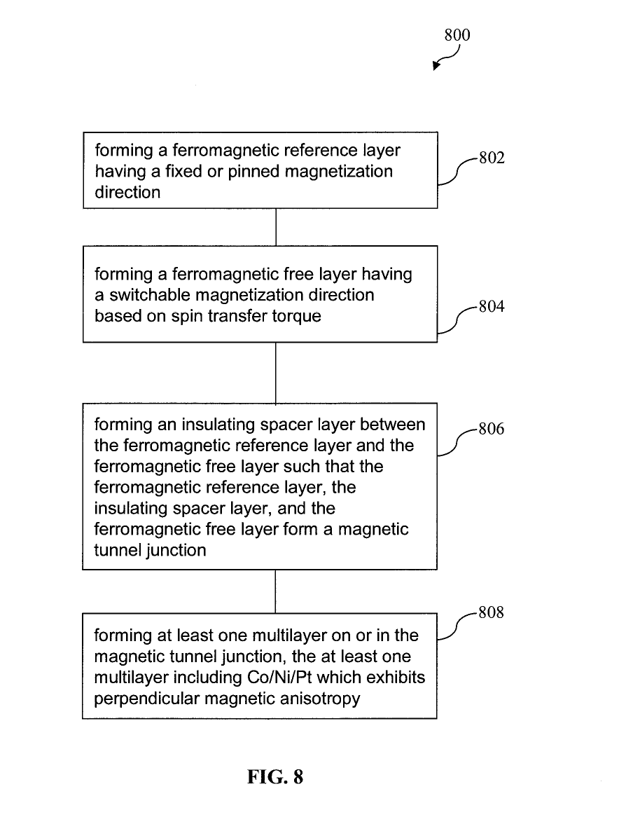

FIG. 8 depicts a flow diagram of a method 800 of fabricating a magnetic element according to an embodiment of the present invention. The method 800 comprising a step 802 of forming a ferromagnetic reference layer 102 having a fixed or pinned magnetization direction, a step 804 of forming a ferromagnetic free layer 104 having a switchable magnetization direction based on spin transfer torque, a step 806 of forming an insulating spacer layer 106 between the ferromagnetic reference layer 102 and the ferromagnetic free layer 104 such that the ferromagnetic reference layer 102, the insulating spacer layer 106, and the ferromagnetic free layer 104 form a magnetic tunnel junction 108, and a step 808 of forming at least one multilayer 130 on or in the magnetic tunnel junction 108, the at least one multilayer 130 including Co/Ni/Pt which exhibits perpendicular magnetic anisotropy. It will be understood that notwithstanding the order in which the above steps are described, the above steps can be performed in any order suitable for a desired end result and various steps can be performed together as appropriate. For example, according to the example embodiment as shown in FIG. 3, it can be understood that the step of forming the ferromagnetic reference layer 102 includes the step of forming the at least one multilayer 130 in the ferromagnetic reference layer 102.

It can be understood that a person skilled in the art would be able to apply appropriate/suitable deposition techniques and conditions known in the art to form the magnetic elements described hereinbefore according to various embodiments of the present invention. Therefore, it is not necessary to describe the specific deposition techniques and conditions herein. For example and without limitation, a direct current magnetron sputtering method may be used for depositing the multilayer according to various embodiments of the present invention, where the base pressure is less than 5×10⁻⁹ Torr. The thickness of each layer can be controlled based on the deposition time. The Co, Ni and Pt layers may be repetitively deposited to form (Co/Ni/Pt)ₙ, where n denotes the stacking number.

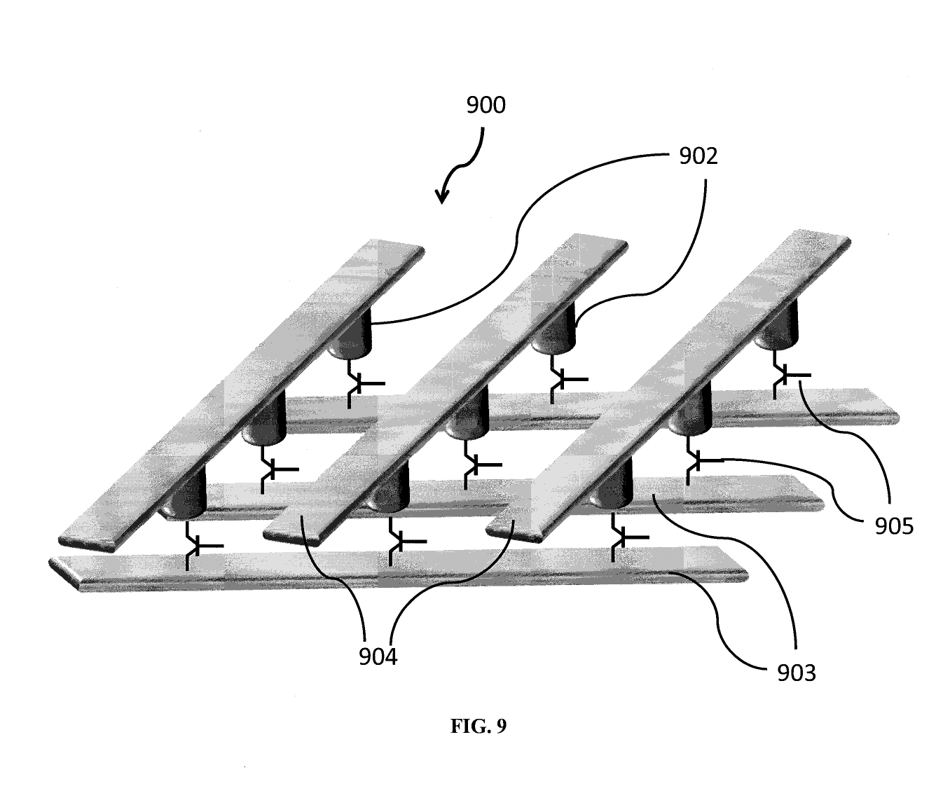

FIG. 9 depicts a schematic drawing of a magnetic memory device 900 according to an example embodiment for illustration purposes only. The magnetic memory device 900 comprises an array/grid of magnetic elements 902 described hereinbefore according to embodiments of the present invention and connected between word lines 903 and bit lines 904. As shown in FIG. 9, each magnetic element 902 may be coupled to the word line 903 via a transistor 905. The transistor 905 is operable to select the magnetic element 902 during the write process and the read process. As mentioned hereinbefore, the magnetic memory device 900 can be any magnetic memory device that is spin current driven, such as but not limited to, a STT-MRAM device.

While embodiments of the invention have been particularly shown and described with reference to specific embodiments, it should be understood by those skilled in the art that various changes in form and detail may be made therein without departing from the spirit and scope of the invention as defined by the appended claims. The scope of the invention is thus indicated by the appended claims and all changes which come within the meaning and range of equivalency of the claims are therefore intended to be embraced.

1. A magnetic element comprising:
a ferromagnetic reference layer having a fixed or pinned magnetization direction;
a ferromagnetic free layer having a switchable magnetization direction based on spin transfer torque;
an insulating spacer layer disposed between the ferromagnetic reference layer and the ferromagnetic free layer such that the ferromagnetic reference layer, the insulating spacer layer, and the ferromagnetic free layer form a magnetic tunnel junction; and
at least one multilayer disposed on or in the magnetic tunnel junction, the at least one multilayer including Co/Ni/Pt which exhibits perpendicular magnetic anisotropy.

2. The magnetic element according to claim 1, wherein the at least one multilayer is disposed on the magnetic tunnel junction such that the at least one multilayer constitutes a compensating layer configured to cancel an external magnetic field towards the ferromagnetic free layer emanating from outside the magnetic tunnel junction.

3. The magnetic element according to claim 2, further comprising a pinning layer ferromagnetically coupled to the ferromagnetic reference layer for pinning the magnetization direction of the ferromagnetic reference layer to the pinning layer, wherein the pinning layer comprises one or more multilayers, each multilayer includes Co/Ni/Pt which exhibits perpendicular magnetic anisotropy.

4. The magnetic element according to claim 3, wherein at least one of the compensating layer and the pinning layer is configured such that the switching field of the compensating layer is less than the switching field of the pinning layer.

5. The magnetic element according to claim 1, wherein the ferromagnetic reference layer comprises a first ferromagnetic material layer and the at least one multilayer.

6. The magnetic element according to claim 5, wherein the ferromagnetic reference layer further comprises:
a second ferromagnetic material layer; and
an interlayer disposed between the first ferromagnetic material layer and the second ferromagnetic material layer for exchange coupling between the first ferromagnetic material layer and the second ferromagnetic material layer, wherein the at least one multilayer is disposed between the first ferromagnetic material layer and the interlayer.

7. The magnetic element according to claim 5, wherein the at least one multilayer is disposed on the first ferromagnetic material layer such that the at least one multilayer constitutes a diffusion barrier for preventing diffusion of one or more elements of the first ferromagnetic layer to the insulating spacer layer.

8. The magnetic element according to claim 5, wherein the first ferromagnetic material layer comprises at least one of (Co/Pd)ₙ, (CoFe/Pd)ₙ, (Co/Pt)ₙ, and (CoFe/Pt)ₙ, where n is a stacking number and is at least 1.

9. The magnetic element according to claim 1, wherein the ferromagnetic free layer comprises a first ferromagnetic material layer and the at least one multilayer.

10. The magnetic element according to claim 9, wherein the ferromagnetic free layer further comprises an interlayer disposed between the first ferromagnetic material layer and the at least one multilayer for exchange coupling between the first ferromagnetic material layer and the at least one multilayer.

11. The magnetic element according to claim 9, wherein the first ferromagnetic material layer comprises at least one of CoFeB.

12. The magnetic element according to claim 1, wherein the at least one multilayer is a multilayer stack including (Co/Ni/Pt)ₙ, where n is a stacking number and is at least 1.

13. The magnetic element according to claim 12, wherein n is a number from 2 to 30.

14. The magnetic element according to claim 1, wherein the thickness of Pt in the at least one multilayer is greater than 0 Angstrom to about 10 Angstrom.

15. A method of fabricating a magnetic element, the method comprising:
forming a ferromagnetic reference layer having a fixed or pinned magnetization direction;
forming a ferromagnetic free layer having a switchable magnetization direction based on spin transfer torque;
forming an insulating spacer layer between the ferromagnetic reference layer and the ferromagnetic free layer such that the ferromagnetic reference layer, the insulating spacer layer, and the ferromagnetic free layer form a magnetic tunnel junction; and
forming at least one multilayer on or in the magnetic tunnel junction, the at least one multilayer including Co/Ni/Pt which exhibits perpendicular magnetic anisotropy.

16. The method according to claim 15, wherein forming the at least one multilayer comprises forming the at least one multilayer on the magnetic tunnel junction such that the at least one multilayer constitutes a compensating layer configured to cancel an external magnetic field towards the ferromagnetic free layer emanating from outside the magnetic tunnel junction.

17. The method according to claim 15, wherein forming the ferromagnetic reference layer comprises forming a first ferromagnetic material layer, and forming the at least one multilayer comprises forming the at least one multilayer as part of the ferromagnetic reference layer.

18. The method according to claim 17, wherein forming the ferromagnetic reference layer further comprises:
forming a second ferromagnetic material layer; and
forming an interlayer between the first ferromagnetic material layer and the second ferromagnetic material layer for exchange coupling between the first ferromagnetic material layer and the second ferromagnetic material layer, wherein the at least one multilayer is formed between the first ferromagnetic material layer and the interlayer.

19. The method according to claim 15, wherein forming the ferromagnetic free layer comprises forming a first ferromagnetic material layer and forming the at least one multilayer comprises forming the at least one multilayer as part of the ferromagnetic free layer.

20. A magnetic memory device comprising an array of magnetic elements, wherein each magnetic element comprising:
a ferromagnetic reference layer having a fixed or pinned magnetization direction;
a ferromagnetic free layer having a switchable magnetization direction based on spin transfer torque;
an insulating spacer layer disposed between the ferromagnetic reference layer and the ferromagnetic free layer such that the ferromagnetic reference layer, the insulating spacer layer, and the ferromagnetic free layer form a magnetic tunnel junction; and
at least one multilayer disposed on or in the magnetic tunnel junction, the at least one multilayer including Co/Ni/Pt which exhibits perpendicular magnetic anisotropy.
